(19) United States
(12) Patent Application Publication
(10) Pub. No.: US 2004/0227216 A1
(43) Pub. Date: Nov. 18, 2004

(54) Flex resistant semiconductor die pad, leadframe, and package

(76) Inventors: Robert F. Mortan, McKinney, TX (US); Lance Wright, Allen, TX (US); Edgar R. Zuniga, McKinney, TX (US)

Correspondence Address: TEXAS INSTRUMENTS INCORPORATED, P O BOX 655474, M/S 3999, DALLAS, TX, 75265

(21) Appl. No.: 10/770,312

(22) Filed: Feb. 2, 2004

Related U.S. Application Data
(60) Provisional application No. 60/471,071, filed on May 16, 2003.

(51) Int. Cl. H01L 21/44; H01L 21/48

(52) U.S. Cl. 257/670; 438/112

(57) ABSTRACT

Disclosed are flex resistant die pads (18), leadframes (16), and high aspect ratio semiconductor packages (10) using the same. Methods for making devices (10, 16, and 18) according to the invention are also disclosed. Preferred embodiments of the invention are described in which tie bars (24) extending outward from the attachment region (20) of a die pad (18) are used to increase flex resistance of die pads (18), leadframes (16), and packages (10).

### RELATED APPLICATION

This application claims priority based on Provisional Patent Application 60/471,071, which has been given a filing date of May 16, 2003. This application and the aforementioned Provisional Patent Application have at least one common inventor and are assigned to the same entity.

### TECHNICAL FIELD

The invention relates to semiconductor device and integrated circuit (IC) packages. More particularly, it relates to new flex resistant die pads and lead frames, and packages using the same.

### BACKGROUND OF THE INVENTION

Semiconductor devices are subject to many competing design goals. When considering resin encapsulated semiconductor devices in terms of mounting approaches, packaged devices may be roughly classified into the pin insertion type and the surface mount type. Since it is very often desirable to minimize the profile of electronic apparatus, surface mount semiconductor devices are often preferred, such as for example, Quad Flat No-lead (QFN) and Small Outline No-lead (SON) packaged devices. Such devices are particularly sought after for use in portable electronics due to their small size. Devices used in such applications are inevitably subjected to numerous challenges brought on by their environment. Increasingly robust and durable devices are always pursued in the arts.

A problem in the arts to which thin devices may be particularly susceptible is flexion. Devices may be flexed by the application of mechanical or thermal forces, or a combination of these and other forces. When flexed, typical surface mount semiconductors are subject to damage or failure, often due to cracking, failure of solder joints, or separation of layers. Efforts have been made in the arts to increase resistance to flexing forces in semiconductor devices through various soldering and encapsulation techniques. The lack of complete success of such approaches leaves room for improvement.

Due to these and other problems new flex resistant semiconductor device packages and components would be useful in the arts.

### SUMMARY OF THE INVENTION

In carrying out the principles of the present invention, in accordance with preferred embodiments thereof, methods and devices of the invention provide flex resistant semiconductor die pads, leadframes, and packages. The methods and devices of the invention provide advantages over the prior art, including but not limited to improved reliability when subjected to board-level thermo-mechanical and mechanical stresses such as temperature cycling, cyclic deflection, and bending. Preferred embodiments of the invention also provide the additional advantage of being amenable to common manufacturing processes, resulting in lowered costs.

According to one aspect of the invention, a die pad for use in a high aspect ratio semiconductor package is disclosed which includes both a die attach region for bearing a semiconductor die and metal tie bars having proximal ends at the die pad die attach region and extending to distal ends for alignment with the ends of the high aspect ratio semiconductor package.

According to an additional aspect of the invention, a die pad for use in a high aspect ratio semiconductor package has strengthening tie bars that include clefts at their outer ends.

According to yet another aspect of the invention, a die pad for use in a high aspect ratio semiconductor package includes tie bars having clefts extending throughout their lengths.

According to still another aspect of the invention, a leadframe embodiment for use in a high aspect ratio semiconductor package is described. Included is a die pad defining a die attach region for bearing a semiconductor die and leads emanating from the die pad of the semiconductor die. Tie bars extend from the die pad to the ends of the leadframe.

According to a further aspect of the invention, a high aspect ratio semiconductor package includes a semiconductor die positioned on a leadframe having a die pad. The leadframe also has numerous leads for electrically connecting to the die as well as tie bars extending from the die attach region to the ends of the leadframe. An encapsulant encapsulates the die, the leadframe, and the inner portions of the tie bars.

Preferred embodiments of the invention are disclosed in which high aspect ratio semiconductor packages according to the invention is adapted for use in QFN and SON assemblies.

According to other aspects of the invention, methods for making a high aspect ratio semiconductor package include steps for forming a leadframe with a die pad defining a die attach region for bearing a semiconductor die. A number of leads are also formed in the leadframe. Tie bars are formed to extend from the die pad to the ends of the leadframe for rigidity.

The invention provides technical advantages including but not limited to providing semiconductor die pads, leadframes, and packages that are resistant to flexing. The inventions may be used to improve board level reliability for mounted QFN and SON packages. These and other features, advantages, and benefits of the present invention can be understood by one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a bottom view of an example of a die pad, leadframe, and semiconductor package according to a preferred embodiment of the invention;

FIG. 2 is an end view of the example of a preferred embodiment of the invention illustrated in FIG. 1;

FIG. 3 is a bottom view of an example of a die pad, leadframe, and semiconductor package according to an alternative preferred embodiment of the invention;

FIG. 4 is an end view of the example of the alternative embodiment of the invention illustrated in FIG. 3;

FIG. 5 is a close-up, bottom, end, perspective view of a portion of the lead frame and die pad of the alternative embodiment of the invention shown in FIGS. 3 and 4;

FIG. 6 is a bottom view of an example of a die pad, leadframe, and semiconductor package according to another alternative preferred embodiment of the invention; and

FIG. 7 is an end view of the example of a preferred alternative embodiment of the invention illustrated in FIG. 6.

References in the detailed description correspond to the references in the figures unless otherwise noted. Descriptive and directional terms used in the written description such as first, second, left, right, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the methods and apparatus of the invention provide improved board level reliability of IC packages. Packages using the invention include metal structures for strengthening points with the potential to be placed under stress by board flexure.

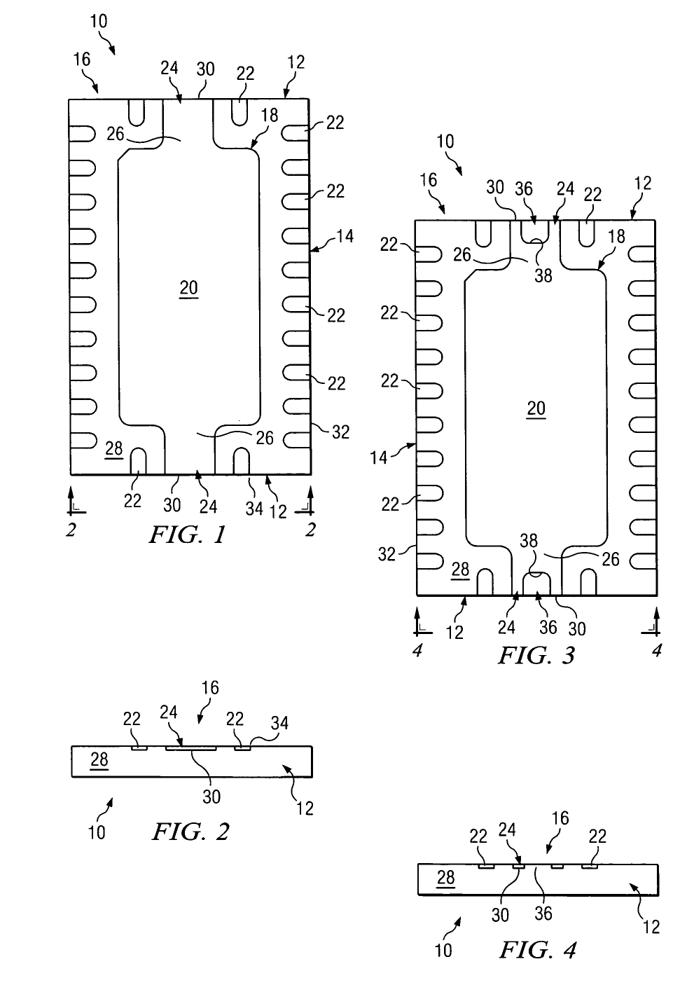

First referring primarily to FIG. 1, exemplary preferred embodiments of the invention are shown. The semiconductor package 10 is a generally rectangular parallelogram and has a high aspect ratio, herein meaning a ratio of length to width greater than one-to-one. For the purposes of description the shorter dimensioned sides (width) are hereinafter denominated the “ends” 12, and the longer dimensioned sides (length) are referred to as simply the “sides” 14. The package 10 in the example illustration appears in a bottom view showing that it includes a leadframe 16. The leadframe 16 has a die pad 18. The die pad 18 defines a die attach region 20 for accepting the attachment of a semiconductor die (not shown). The leadframe 16 also has numerous conductive leads 22 extending outward from the die attach region 20 of the die pad 18 for electrically connecting to the semiconductor die as known in the arts. The die pad 18 also has tie bars 24. The tie bars 24 each preferably extend from a proximal end 26 at the die pad 18 to a generally perpendicular distal end 30. The tie bars 24 preferably run to the ends 12 of the package 10 and provide rigidity and strength. Typically, the package 10 includes a resinous encapsulant 28 surrounding the die, die pad 18, and leadframe 16. The edges 32 of the leads 22 and edges 34 of the distal ends 30 of the tie bars 24 are preferably not encapsulated, but are exposed when individual packages 10 are singulated as known in the arts. The edge 34 of the distal end 30 of a tie bar 24 can be seen in FIG. 2, depicting an end view of the example of a semiconductor package 10 end 12 shown and described with reference to FIG. 1.

The presently most preferred embodiments of the invention are illustrated in the views of FIGS. 3, 4, and 5. FIG. 3 shows a bottom view of a high aspect ratio semiconductor package 10 with a leadframe 16 and die pad 18 configuration as described above. Tie bars 24 extend from the die attach region 20 of the die pad 18 to the ends 12 of the package 10. The tie bars 24 each preferably also have a cleft 36 extending inward from their distal ends 30 towards their proximal ends 26. It is preferred for the tie bar 24 to extend to near the ends 12 of the package 10 with the inner surface 38 of the clefts 36 beginning near distal ends 30 of the tie bars. The exact dimensions and shapes of the clefts 36 are not crucial to the implementation of the invention so long as the clefts 36 span the distal ends 30 of their respective tie bars 24. The clefts 36 increase the ease of saw singulation of individual packages 10 using the invention without excessively reducing the strength and rigidity of the tie bars 24. A side view of the end 12 a package 10 using the invention is shown in FIG. 4 offering a depiction of an example as seen from the end 12 of the package 10.

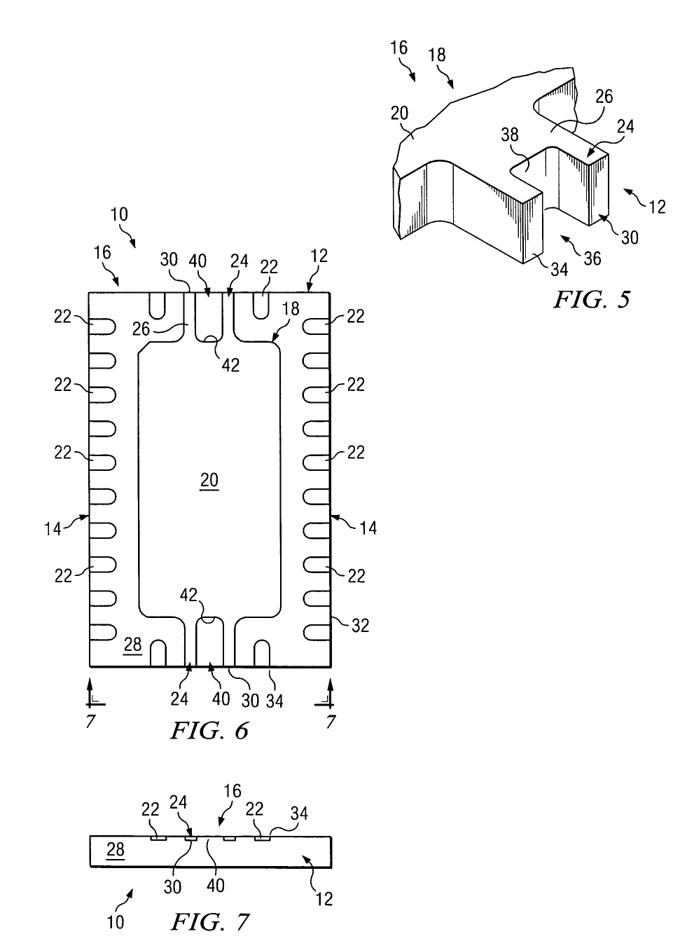

FIG. 5 provides an alternative bottom, end, perspective view of a leadframe 16 with a tie bar 24 extending from the die pad 18. The tie bar 24 has a cleft 36 extending to its distal end 30. Encapsulant is omitted from FIG. 5 to better reveal the structure and features of the tie bar 24.

Additional alternative embodiments of the invention are shown in FIGS. 6 and 7. The essential features of the semiconductor package 10, leadframe 16, and die pad 18 are as described above with the notable exception that the tie bars 24 have elongated clefts 40 extending from their proximal ends 26 at the die attach region 20 to their distal ends 30. It should be understood that the inner surface 42 of the cleft 40 is situated at the extreme proximal end 26 of the tie bar 24 adjacent to the die attach region 20. This configuration 10 is readily singulated by ordinary sawing techniques.

Thus, the invention provides robust die pads and leadframes, and semiconductor packages using the same. While the invention has been described with reference to certain illustrative embodiments, the methods and apparatus described are not intended to be construed in a limited sense. Various modifications and combinations of the illustrative embodiments as well as other advantages and embodiments of the invention will be apparent to persons skilled in the art upon reference to the description and claims.

We claim:

1. A die pad for use in a high aspect ratio semiconductor package comprising:
a die pad defining a die attach region for bearing a semiconductor die; and
tie bars having proximal ends at the die pad die attach region and extending to distal ends for alignment with the ends of the semiconductor package.

2. A die pad for use in a high aspect ratio semiconductor package according to claim 1 wherein the tie bars further comprise clefts at their distal ends.

3. A die pad for use in a high aspect ratio semiconductor package according to claim 1 wherein the tie bars further comprise clefts extending from their proximal ends to their distal ends.

4. A leadframe for use in a high aspect ratio semiconductor package comprising:
a die pad defining a die attach region for bearing a semiconductor die;
a plurality of leads emanating from the die pad at the die attach region for electrically connecting to a semiconductor die; and
tie bars having proximal ends at the die pad die attach region and extending to distal ends at the ends of the leadframe.

5. A leadframe for use in a high aspect ratio semiconductor package according to claim 4 wherein the tie bars further comprise clefts at their distal ends.

6. A leadframe for use in a high aspect ratio semiconductor package according to claim 4 wherein the tie bars further comprise clefts extending from their proximal ends to their distal ends.

7. A high aspect ratio semiconductor package comprising:
a semiconductor die;
a leadframe having a die pad defining a die attach region for bearing the die, the leadframe also having a plurality of leads for electrically connecting to the semiconductor die, wherein the die pad further comprises tie bars extending from proximal ends at the die attach region to distal ends at the ends of the leadframe; and
an encapsulant encapsulating the die, the leadframe, and the proximal ends of the tie bars.

8. A high aspect ratio semiconductor package according to claim 7 wherein the tie bars further comprise clefts at their distal ends.

9. A high aspect ratio semiconductor package according to claim 7 wherein the tie bars further comprise clefts extending from their proximal ends to their distal ends.

10. A high aspect ratio semiconductor package according to claim 7 adapted for use in a QFN assembly.

11. A high aspect ratio semiconductor package according to claim 7 adapted for use in a SON assembly.

12. A method of making a high aspect ratio semiconductor package comprising the steps of:
forming a leadframe having a die pad defining a die attach region for bearing a semiconductor die, the leadframe also having a plurality of leads for electrically connecting to the semiconductor die;
forming tie bars extending from proximal ends at the die attach region of the die pad to distal ends at the ends of the leadframe;
operably attaching a die to the die pad; and
encapsulating the die, the leadframe, and the proximal ends of the tie bars.

13. A method of making a high aspect ratio semiconductor package according to claim 12 further comprising the step of forming clefts at the distal ends of the tie bars.

14. A method of making a high aspect ratio semiconductor package according to claim 12 further comprising the step of forming clefts extending from the proximal ends of the tie bars to their distal ends.

15. A method of making a high aspect ratio semiconductor package according to claim 12 further comprising the step of configuring the package as a QFN package.

16. A method of making a high aspect ratio semiconductor package according to claim 12 further comprising the step of configuring the package as an SON package.
